(19) United States
(12) Patent Application Publication
(10) Pub. No.: US 2019/0115986 A1
(43) Pub. Date: Apr. 18, 2019

(54) SWITCH MODE DIRECT CURRENT-TO-DIRECT CURRENT (DC-to-DC) CONVERTERS WITH REDUCED SPURIOUS NOISE EMISSION

(71) Applicant: TEXAS INSTRUMENTS INCORPORATED, Dallas, TX (US)

(72) Inventor: Joerg Erik GOLLER, Tiefenbach (DE)

(21) Appl. No.: 15/914,944

(22) Filed: Mar. 7, 2018

Related U.S. Application Data
(60) Provisional application No. 62/574,000, filed on Oct. 18, 2017.

(51) Int. Cl. H04B 15/04; H02M 1/44; H02M 1/12; H02M 3/158; H03K 7/08; H03K 19/003

(52) U.S. Cl. CPC H04B 15/04; H02M 1/44; H02M 1/12; H04B 2215/065; H03K 7/08; H03K 19/00346; H02M 3/158

(57) ABSTRACT

An integrated circuit comprises a timebase generator that comprises a linear feedback shift register (LFSR) and a switch mode direct current-to-direct current (DC-to-DC) voltage converter coupled to the timebase generator.

### CROSS-REFERENCE TO RELATED APPLICATIONS

The present application claims priority to U.S. Provisional Patent Application No. 62/574,000, which was filed Oct. 18, 2017, is titled “Switch Mode Converter With Reduced Noise And Electromagnetic Interference,” and is hereby incorporated herein by reference in its entirety.

### BACKGROUND

Direct current-to-direct current (DC-to-DC) converters find many applications in electronic devices. For example, DC-to-DC converters are used in mobile electronic devices to convert battery power to different voltage levels specified by different chips in the device-display drivers, camera peripherals, digital processors, field programmable gate arrays (FPGA), application specific integrated circuits (ASICs), interface devices, vibrator devices, and others. Some DC converters receive an input DC voltage and step it down to a lower DC voltage. Some DC converters receive an input DC voltage and step it up to a higher DC voltage. Some DC converters are configurable or controllable to both step up and step down DC voltage. In some cases, the operation of these DC-to-DC converters is based on switching circuit operation modes and hence these DC-to-DC converters rely on a timebase generator to control the switching frequency.

### SUMMARY

In accordance with at least one example of the disclosure, an integrated circuit comprises a timebase generator that comprises a linear feedback shift register (LFSR) and a switch mode direct current-to-direct current (DC-to-DC) voltage converter coupled to the timebase generator.

In accordance with at least one example, an integrated circuit comprises a timebase generator and a switch mode direct current-to-direct current (DC-to-DC) voltage converter. The timebase generator comprises a Fibonacci linear feedback shift register (LFSR) and a comparator, a first input of the comparator coupled to the Fibonacci LFSR, a second input of the comparator coupled to a voltage reference, and an output of the comparator coupled to a clock input of the Fibonacci LFSR. The switch mode DC-to-DC voltage converter is coupled to the output of the comparator of the timebase generator.

In accordance with at least one example, an integrated circuit comprises a timebase generator and a switch mode direct current-to-direct current (DC-to-DC) voltage converter. The timebase generator comprises a Fibonacci linear feedback shift register (LFSR), an output of an exclusive OR (XOR) gate of the Fibonacci LFSR coupled to an input of a register of the Fibonacci LFSR and two inputs of the XOR gate coupled to two outputs of registers of the Fibonacci LFSR; a comparator, a first input of the comparator coupled to the Fibonacci LFSR, a second input of the comparator coupled to a voltage reference; and a digital divider, an input of the digital divider coupled to an output of the comparator and an output of the digital divider coupled to a clock input of the Fibonacci LFSR. The DC-to-DC voltage converter is coupled to the output of the comparator of the timebase generator.

### BRIEF DESCRIPTION OF THE DRAWINGS

For a detailed description of various examples, reference will now be made to the accompanying drawings in which:

FIG. 1 shows a DC-to-DC converter chip in accordance with various examples.

FIG. 2A shows a timebase generator in accordance with various examples.

FIG. 2B shows a sequence of pseudo-random numbers generated by a linear feedback shift register (LFSR) in accordance with various examples.

FIG. 2C shows another timebase generator in accordance with various examples.

FIG. 3 shows a Fibonacci linear feedback shift register (LFSR) in accordance with various examples.

FIG. 4 shows a timebase generator processing method in accordance with various examples.

FIG. 5 shows a comparison between switching noise using a constant switching frequency and switching noise using a varying switching frequency in accordance with various examples.

FIG. 6 shows adaptations of varying switching frequency in accordance with various examples.

FIG. 7 shows a block diagram of a DC-to-DC converter in accordance with various examples.

FIG. 8 shows a clock generator in accordance with various examples.

### DETAILED DESCRIPTION

Switch mode DC-to-DC converters rely on switching a circuit mode of operation, where the switching is inherent to producing an output DC voltage that is independent from the voltage level of the input DC voltage. In examples, the output DC voltage is higher than the voltage level of the input DC voltage. In examples, the output DC voltage is lower than the input DC voltage. In examples, the output DC voltage is about the same as the input DC voltage but is coupled indirectly to the input DC voltage. This is the sense in which switch DC-to-DC converters are said above to produce an output DC voltage that is independent from the voltage level of the input DC voltage. This switching causes an undesirable noise spur at the switching frequency that can be detected at various points in the switch mode DC-to-DC converters—in the input voltage, in internal points, and at the output voltage. In examples, this noise spur interferes with electronic device and system performance, both performance within the switch mode DC-to-DC converter and performance of electronic devices receiving the DC voltage output by the switch mode DC-to-DC converter.

To solve the foregoing problem, the present disclosure teaches dithering or shifting the frequency of the switching in a pseudo-random pattern that spreads the switching noise across a range of frequencies, thereby lowering the amplitude of switching noise at any one frequency. In examples, a linear feedback shift register (LFSR) is used to generate a sequence of N-bit values that repeats continuously. In examples, a LFSR is used to generate a sequence of 2^{(N)}−1 different N-bit values. Because in some examples the values produced by the LFSR are pseudo-randomly distributed and none of the values are repeated in a cycle of the LFSR, a modulation controlled by the above mentioned sequence of values generated by the LFSR does not introduce an additional low frequency noise source into the switch mode DC-to-DC converter. In examples, the output values of the LFSR drive a control that varies the switching frequency of the switch mode DC-to-DC converter in a narrow range of frequencies around a target switching frequency. To achieve design objectives of switch mode DC-to-DC converters, an optimal or target switching frequency is defined, and switching at a frequency too far different (e.g., beyond a threshold) from that target switching frequency degrades performance of the switch mode DC-to-DC converter unacceptably. The framework for reducing switching noise described herein has application to reducing switching noise in clock generator chips as well, for example in environments where cycle-to-cycle jitter can be tolerated better than switching noise.

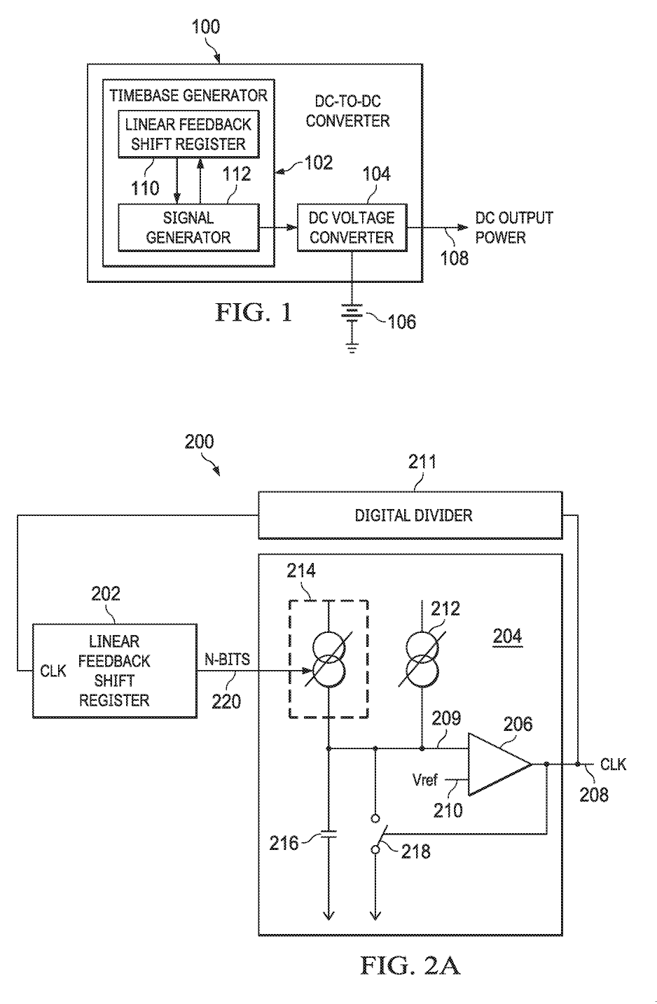

FIG. 1 depicts an illustrative switch mode DC-to-DC converter integrated circuit chip 100. In examples, the switch mode DC-to-DC converter chip 100 comprises a timebase generator 102 and a DC voltage converter 104. The DC voltage converter of the switch mode DC-to-DC converter chip 100 is connected to a battery 106 that inputs DC power and is connected to a DC output power 108 that provides converted DC voltage (boosted up, stepped down, or equal to the input voltage received from the battery 106). The timebase generator 102 generates a switching signal or timebase that is supplied to the DC voltage converter 104 to switch its power stage to perform its voltage conversion function. As used herein, a timebase signal refers to a signal that contains patterns or events. In an example, the timebase signal is a signal that contains events constituted by a rising edge of a pulse. In an example, the timebase signal is a signal that contains events constituted by a falling edge of a pulse. In an example, the timebase signal is a signal that contains events constituted by the peak value of a triangular wave signal. In an example, the timebase signal is a signal that contains events constituted by a minimum value of a triangular wave signal. In other examples, the timebase signal is a signal that contains events constituted by other patterns.

By switching a mode of circuit operation of a power stage within the DC voltage converter 104 in response to the switching signal generated by the timebase generator 102, the DC voltage converter 104 establishes the DC voltage of the output of the switch mode DC-to-DC converter chip 100. In examples, the DC voltage converter comprises a boost converter, a buck converter, or a buck-boost converter switch mode DC-to-DC voltage converter circuit topology.

The timebase generator 102 comprises a linear feedback shift register (LFSR) 110 and a signal generator 112. The LFSR 110 and the signal generator 112 are communicatively coupled to each other. The signal generator 112 provides a clock signal to the LFSR 110 that causes it to shift bits serially through its registers. In examples, the signal generator 112 also provides a switching signal from the timebase generator 102 to the DC voltage converter 104. The digital value stored by the LFSR 110 is output to the signal generator 112 and causes the switching signal output by the signal generator 112 to vary in switching frequency. Said in other words, the LFSR 110 is configured to vary the frequency of the switching signal generated by the timebase generator 102. In examples, the timebase signal output by the signal generator 112 is further conditioned to generate the switching signal used by the DC voltage converter 104.

In examples, the LFSR 110 is a Fibonacci type of LFSR. In examples, the LFSR 110 is a Galois type of LFSR. In examples, the LFSR 110 is replaced with another component that generates a multi-bit sequence of pseudo-random numbers. Some of the output values of registers of the LFSR 110 are fed back to the inputs of one or more logic gates (not shown in FIG. 1) to generate an input signal to an initial register of the LFSR 110. Because the LFSR 110 is clocked (e.g., the shift is controlled by the clock signal) by the output of the signal generator 112, the LFSR 110 and the signal generator 112 do not get out of synchronization. Said in other words, generation of a next pseudo-random pattern or value of the LFSR 110 (e.g., changing switching signal frequency) is based on the last clock edge that was generated.

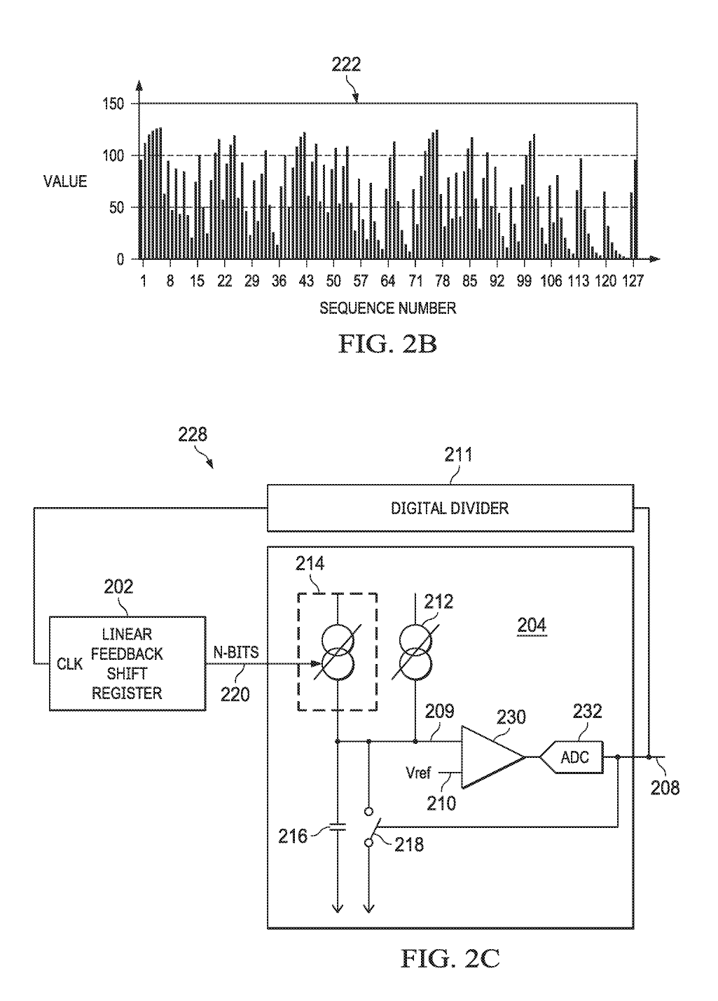

FIG. 2A shows an illustrative timebase generator 200. In examples, the timebase generator 200 is used to implement the timebase generator 102 described above with reference to FIG. 1. In examples, the timebase generator 200 is used to implement a clock generator. In examples, the timebase generator 200 comprises a LFSR 202 and a signal generator 204. In examples, the LFSR 202 is a Fibonacci LFSR. In examples, the LFSR 202 is a Galois LFSR.

In examples, the signal generator 204 comprises a comparator 206 that outputs a high logic level as a clock signal 208 and/or timebase when a voltage on a first input 209 exceeds the voltage of a voltage reference coupled to a second input 210. The timebase is used by the DC voltage converter 104 to switch.

In examples, the signal generator 204 further comprises a constant current source 212 and a varying current source 214, a capacitor 216, and a switch 218 (e.g., a transistor). A current output of the constant current source 212 and a current output of the varying current source 214 are coupled to a first lead of the capacitor 216. A second lead of the capacitor is coupled to ground. The first lead of the capacitor 216 is also coupled to the first input 209 of the comparator 206. The output of the comparator 206 (e.g., clock signal 208) is coupled to a control lead of the switch 218. A first lead of the switch 218 is coupled to the first lead of the capacitor 216 and a second lead of the switch 218 is coupled to ground. When the switch 218 is closed, the first lead of the switch is connected to the second lead of the switch, and the first lead of the capacitor 216 is hence coupled to ground. When the switch 218 is open, the first lead of the switch is disconnected from the second lead of the switch 218. In examples, the output of the signal generator 204 is a pulse of clock pulse. The LFSR 202 is coupled to the comparator 206, for example coupled via the constant current source 212 and the varying current source 212.

In examples, this clock signal 208 output by the signal generator 204 is fed back to a clock input of the LFSR 202 which controls when the LFSR 202 shifts and outputs a different pseudo-random number. In examples, the output 208 of the signal generator 204 is coupled to the input of a digital divider 211, and the output of the digital divider 211 is coupled to the clock input of the LFSR 202. The digital divider 211 divides the output 208 of the signal generator 204 by an integer. In examples, the digital divider 211 divides the output 208 of the signal generator 204 by an integer multiple of 2. Thus, the digital divider 211 divides the output 208 by one of 2, 4, 8, 16, 32, . . . , 2^{k} where k is a positive integer value. In examples, the digital divider 211 divides the output 208 by one of 3, 5, 6, 7, 9, 10, or another integer value. The digital divider 211, in examples, further contributes to decreasing switching noise in the switch mode DC-to-DC converter 100. The optional digital divider 211 has the effect of causing the signal generator 204 to maintain the same switching frequency for a plurality of cycles rather than changing on each cycle of the timebase.

The voltage at the first lead of the capacitor 216 and hence the voltage of the first input 209 ramps up as current produced by the constant current source 212 and varying current from the varying current source 214 is collected by the capacitor 216 (e.g., charging the capacitor 216). Said in other words, the capacitor 216 in effect sums the current output by the constant current source 212 and the varying current source 214 to produce a voltage value. When the voltage at the first input 209 exceeds the voltage of the voltage reference present at the second input 210 of the comparator 206, the comparator 206 outputs a logic high value on the clock signal 208. When the clock signal 208 is high, this causes the switch 218 to close and rapidly discharge the capacitor 216 to ground. As a result of discharging, the voltage at the first lead of the capacitor drops and hence the voltage at the first input 209 drops below the voltage reference coupled to the second input 210, and the output of the comparator 206 outputs a low logic level. The low logic level causes the switch 218 to open again, and allows the capacitor 216 to resume charging from constant current source 212 and varying current source 214.

If the varying current source 214 were not in the signal generator 204 or if it were turned off, the current charging the capacitor 216 would be constant, and the frequency of the clock signal 208 (and switching signal) would be a constant frequency. The output 220 of the registers of the LFSR 202 comprise an N-bit number that controls the varying current source 214 to produce more or less current as the N-bit number is larger or smaller. In some contexts, the output 220 of the registers of the LFSR 202 is referred to as an N-bit control word. In examples, the output 220 of the registers of the LFSR 202 modifies a timebase signal generated by the signal generator 204 in a binary weighted manner. In examples, the LFSR 202 comprises 7 registers and hence outputs a 7-bit number to the varying current source 214 from b0000001 to b1111111 (b0000000 may be an excluded value). In examples, the sequence of pseudo-random numbers produced by the LFSR 202 are represented in graph 222 as shown in FIG. 2B. If a different initial seed value for the LFSR 202 were used, the sequence of pseudo-random numbers would start at a different point in the sequence. The LFSR 202 starts with an initial seed value at sequence step 1, it produces a different value at sequence step 2, it produces a different value at sequence step 3, and so on through different values between 1 and 127 through the remaining sequence steps to step 127. After sequence step number 127, the LFSR 202 again produces the initial seed value at sequence step 128. The numbers generated by the LFSR 202 are said to be pseudo-random because they are not random but deterministic based on the initial seed value. The numbers generated by the LFSR 202 are also said to be pseudo-random because their values are generally randomly distributed between 1 and 127.

It is the nature of the configuration of the illustrative LFSR 202 that the 7-bit numbers output by its registers occur in a pseudo-random sequence, and that this sequence does not repeat any values until all 127 permitted values have been produced (although in some examples, it is possible for the sequence to include some repeated values). In examples this is referred to as a maximum length sequence of output values for the LFSR 202. Different LFSRs have different maximum length sequences associated with the number of registers the LFSR contains. For example, a maximum length sequence of a 9-bit Fibonacci LFSR is 511, and a maximum length sequence of an 11-bit Fibonacci LFSR is 2047. It is noted that not all LFSRs are maximum length LFSRs. In examples, the sequence length of an LFSR depends on a feedback path of the LFSR.

FIG. 2B shows a sequence of pseudo-random numbers produced by the LFSR 202. A pseudo-random number is associated to or each sequence number (e.g., the sequence of integers 1, 2, 3, . . . , 2^{N}−1). The pseudo-random number is not a linear function of its associated sequence number. The pseudo-random numbers are substantially randomly distributed over the sequence.

FIG. 2C shows another illustrative timebase generator 228 that is an alternative example to the timebase generator 200 described above with reference to FIG. 2A. The timebase generator 228 is substantially similar to the timebase generator 200 described above, with the difference that the clock signal 208 is produced by the combination of a differential amplifier 230 and an analog-to-digital converter (ADC) 232. The differential amplifier 230 is coupled to the first lead of the capacitor 216 on its first input 209 and is coupled to a voltage reference at its second input 210. The differential amplifier 230 outputs an analog signal that is based on its first and second inputs to the ADC 232, and the ADC 232 produces the clock signal 208 that feds back into the LFSR 202 and to the switch 218.

In examples, the implementation of the timebase generator 102, 200, 228 described herein provides one or more benefits. In examples, the implementation of the timebase generator 102, 200, 228 is manufactured using a small amount of area on an integrated circuit. In examples, the implementation of the timebase generator 102, 200, 228 is applicable to a wide variety of circuit designs. In examples, the implementation of the timebase generator 102, 200, 228 promotes starting and stopping without disrupting a system relying on the switching signal it outputs. In examples, the implementation of the timebase generator 102, 200, 228 consumes little power.

The signal generator 204 can take many forms that are different from the examples described above with reference to FIG. 2A and FIG. 2B. In examples, a different signal generator generates a pulse-width timebase. In examples, a signal generator generates a minimum time on type of timebase. The disclosure contemplates a broad variety of mechanisms for receiving a command word in the form of a pseudo-random number generated by a LFSR and transforming this pseudo-random number into a timebase. The timebase is then used to control a switch of DC voltage converter 104.

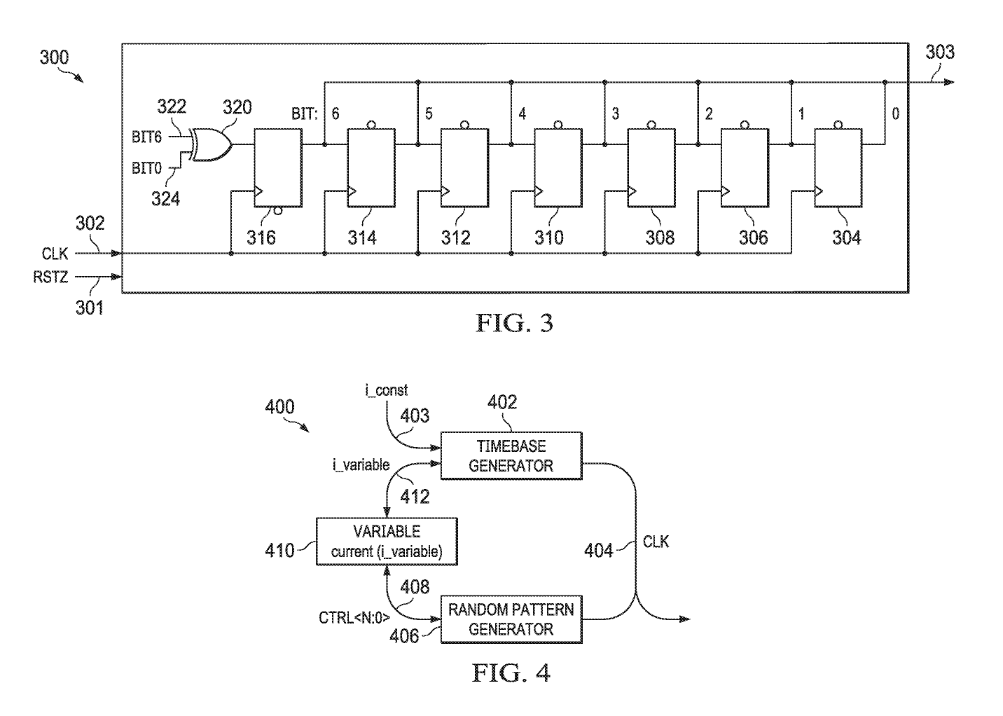

FIG. 3 shows an illustrative 7-bit Fibonacci LFSR 300. In examples, the LFSR 300 is, or is part of, the LFSR 110 of FIG. 1. In examples, the LFSR 300 is, or is part of, the LFSR 202 of FIG. 2A. In examples, the LFSR 300 comprises a reset zero input 301, a clock input 302, a 7-bit parallel output 303, a first register 304, a second register 306, a third register 308, a fourth register 310, a fifth register 312, a sixth register 314, and a seventh register 316. In examples, each of the registers 304-316 is a flip-flop. The output of the seventh register 316 is connected to the input of the sixth register 314. The output of the sixth register 314 is connected to the input of the fifth register 312. The output of the fifth register 312 is connected to the input of the fourth register 310. The output of the fourth register 310 is connected to the input of the third register 308. The output of the third register 308 is connected to the input of the second register 306. The output of the second register 306 is connected to the input of the first register 304. The output 324 of the first register 304 and the output 322 of the seventh register 316 are processed in an exclusive or operation (XORed) by an XOR gate 320 (connections to the XOR gate 320 omitted from FIG. 3 for clarity) to determine the input of the seventh register 316.

The LFSR 300 is configured to be loaded with an initial seed value on power up of the device. The seed value may be any 7 bit value, excluding b0000000. While not illustrated as coupled to the registers 304-316 in FIG. 3 to avoid cluttering the figure, in examples the reset zero input 301 is coupled to a set or a reset input of the registers 304-316. As illustrated in FIG. 3, the seventh register 316 is configured to set its Q output to logic high when the reset zero input 301 is set to low logic and the first through sixth registers 304-314 are configured to set their Q outputs to logic low when the reset zero input 301 is set to low logic. Thus, the illustrative 7-bit Fibonacci LFSR 300 of FIG. 3 is depicted as configured to initialize with a seed value of b1000000. In other examples, the 7-bit Fibonacci LFSR 300 is configured to initialize with a different seed value different from b1000000 and different from b0000000.

FIG. 4 is a flowchart of an illustrative process 400 of generating the clock output or the switching signal of the timebase generator 200 of FIG. 2A or of timebase generator 102 of FIG. 1. The process 400 may continuously repeat while operating the timebase generator 102, 200 and while operating the switch mode DC-to-DC converter 100. At block 402, a timebase generator determines a clock period as a function of a constant current 403 and of a variable current 412, such as those produced by current sources 212, 214 in FIG. 2A. This clock period controls a clock 404 that has a frequency equal to the reciprocal of the period determined at block 402. The clock period is changing on each cycle through the loop of the process 400. In examples, the clock switches from low to high and back to low only one time during each cycle through the loop of the process 400.

The clock 404 controls a random pattern generator at block 406 to set a control value 408 to a newly calculated control value, in response to the clock 404. In examples, the random pattern generator is a LFSR. In examples, the random pattern generator is a Fibonacci LFSR. In examples, the random pattern generator is one of a 7-bit Fibonacci LFSR, a 9-bit Fibonacci LFSR, an 11-bit Fibonacci LFSR, a 15-bit Fibonacci LFSR, or a 17-bit Fibonacci LFSR. In examples, the random pattern generator is a Galois LFSR. The LFSR may be configured to generate a maximum length sequence of pseudo-random values, none of which repeats during the maximum length cycle. At the end of the sequence of values, the sequence starts a new cycle, starting from the initial value of the sequence. Any initial seed value can be established for the LFSR, excepting a 0 value (b00 . . . 0).

The control value 408 controls the variable current 412, where, in at least some examples, the amplitude of the variable current is a linear function of the control value 408. As the clock 404 pulses high and back low, the LFSR shifts values through its registers and sets a different value, and the different value establishes a different variable current, and the different variable current changes the clock period in the next cycle through the loop of the process 400.

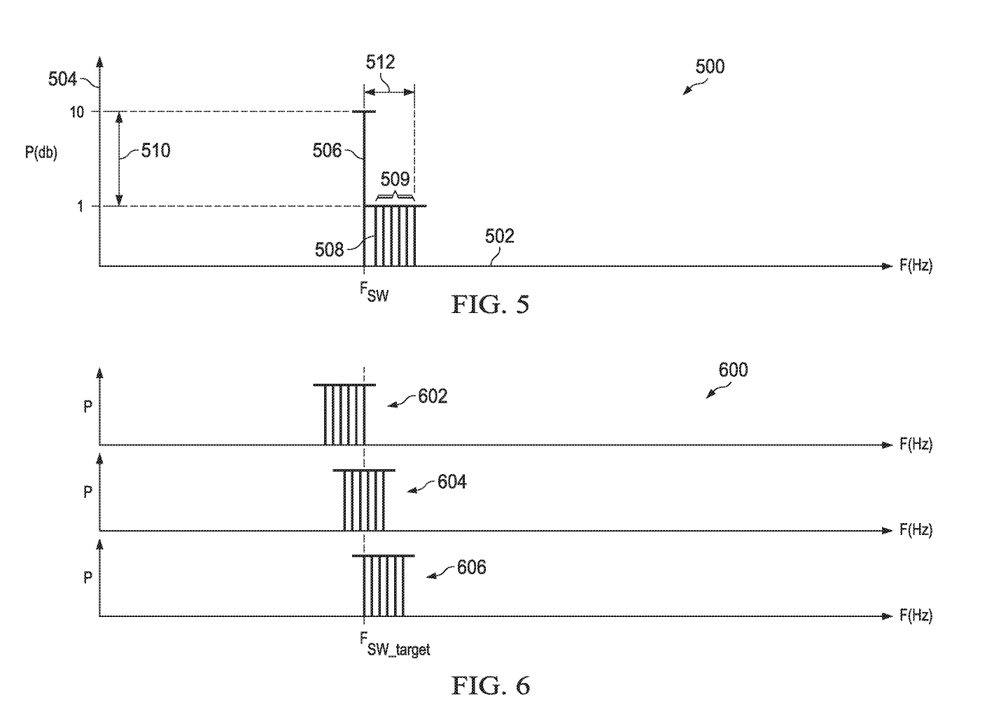

FIG. 5 compares illustrative switching noise associated with a constant frequency switching signal versus switching noise associated with a varying frequency switching signal. An illustrative graph 500 comprises an X-axis 502 that represents frequency and a Y-axis 504 that represents power in a log base 10 scale. A first trace 506 represents the switching noise in a conventional switch mode DC-to-DC converter at the switching frequency Fsw. A second trace 508 is an example trace of a plurality of traces 509 that result from spreading the switching signal to a plurality of different frequencies as described herein. While only a few traces of the varying frequency switching noise are illustrated in FIG. 5, the number of the plurality of traces 509 may equal the number of different values output by the LFSR in the timebase generator 102, 200. In examples, the plurality of traces 509 comprise 127 traces, 511 traces, 2047 traces, 32767 traces, 131071 traces, or some other number of traces. The second trace 508 represents the switching noise in the switch mode DC-to-DC converter 100 described above at a single frequency of a plurality of frequencies of switching. The difference in power between the switching noise in a conventional switch mode DC-to-DC converter (first trace 506) and the switching noise in traces 509 when spreading the switching signal frequencies is illustrated as difference 510 (Y-axis is LOG base 10 scale). The spread of switching signal frequencies is illustrated as the spread switching signal frequency bandwidth 512.

While only a few traces of the varying frequency switching noise are illustrated in FIG. 5, the number of traces may equal the number of different values output by the LFSR in the timebase generator 102, 200. For example, when using a 7-bit Fibonacci LFSR, as illustrated in FIG. 3, 127 traces would be present. Because the sum of the noise energy in the frequency spread of all the 127 traces would be equal to the amplitude of the first trace 506, the noise energy of each of the 127 traces would be much diminished. (Note: the scale of the Y-axis 504 is log base 10 scale to make FIG. 5 more readable.) In a theoretical maximum, the energy in the frequency spread switching signal would be 1/127 or −21 dB (10 LOG(1/127)) the energy of the noise in the non-spread noise spur. In practice, less than the theoretical maximum energy attenuation would be expected.

In examples, the distance between the traces 509 and hence the total variation of the frequency of the switching signal is determined, at least in part, by the range of varying current output by the varying current source 214 in response to the output of the LFSR 202. The greater the maximum output of the varying current source 214, the wider the variation of frequency of the switching signal. In examples, the frequency varies less than 10% of a switching frequency target frequency. For example, if the target frequency is 3 MHz, the switching signal ranges over a frequency bandwidth of less than 10% of 3 MHz or less than 300 kHz. For example, the switching frequency may vary from 2.7 MHz to 3 MHz, from 2.85 MHz to 3.15 MHz, from 3 MHz to 3.3 MHz, or over smaller bandwidths. In examples, if the switching signal is varied over a greater range than 15%, the performance of the switch mode DC-to-DC converter 100 is degraded. In examples, if the switching signal is varied over a greater range than 10%, the performance of the switch mode DC-to-DC converter 100 is degraded. In examples, if the switching signal is varied over a greater range than 8%, the performance of the switch mode DC-to-DC converter 100 is degraded. In examples, if the switching signal is varied over a greater range than 6%, the performance of the switch mode DC-to-DC converter 100 is degraded.

FIG. 6 shows the frequency bandwidth of the switching signal varying from a minimum frequency to a maximum frequency, where the maximum frequency is the target switching frequency in the first plurality of traces 602. In a second plurality of traces 604 the switching signal varies from a minimum frequency to a maximum frequency, where the target switching frequency is in about the middle of the varying switching signal frequency bandwidth. In a third plurality of traces 606, the switching signal varies from a minimum frequency that is the target switching frequency to a maximum frequency.

The different plurality of traces 602, 604, 606 can be established by varying the fixed current output of the constant current source 212 in FIG. 2A. In the first plurality of traces 602, the constant current source is set to the level of the lowest frequency. In the third plurality of traces 606, the constant current source is set to the level associated with the target switching frequency. In the second plurality of traces 604, the constant current source is set to a level between the levels of the first plurality of traces 602 and the third plurality of traces 606. The structure of the timebase generator 200 is flexible and can be adapted by designers to achieve different switching frequencies and different switching frequency bandwidths (the range of variation of switching signal frequency).

Referring to FIG. 2A, in examples, the varying current source 214 is implemented by a plurality of separate varying current source components, where each separate varying current source component is switched on or off by one of the output bits of the N-bit LFSR 202. The number of varying current source components is equal to the number N of the N-bit LFSR 202.

In an example, the constant current source 212 is configured to output 10 μA (microamps), a first component of the varying current source is configured to output 6.3 nA (nanoamps), a second component of the varying current source 214 is configured to output 12.6 nA, a third component of the varying current source 214 is configured to output 25.2 nA, a fourth component of the varying current source is configured to output 50.4 nA, a fifth component of the varying current source 214 is configured to output 100.8 mA, a sixth component of the varying current source 214 is configured to output 201.6 nA, and a seventh component of the varying current source 214 is configured to output 403.2 nA. Each of the components of the varying current source 214 turns on and off based on a corresponding bit in the output of the LFSR 202. When none of the component current sources of the varying current source 214 is turned on, the output of the varying current source 214 is zero, the capacitor 216 is charged only by the constant current source 212, the period of the clock 208 is longer, and the frequency of the switching signal is lower. When all of the component current sources of the varying current source 214 are switched on (e.g., the LFSR 202 outputs the value b1111111=127), the capacitor 216 is charged by about 10 μA current from the constant current source 212 and by about 800 nA current from the varying current source 214, the period of the clock 208 is shorter, and the frequency of the switching signal is higher. In different examples, different amounts of current may be sourced by the constant current source 212 and by the component current sources of the varying current source 214.

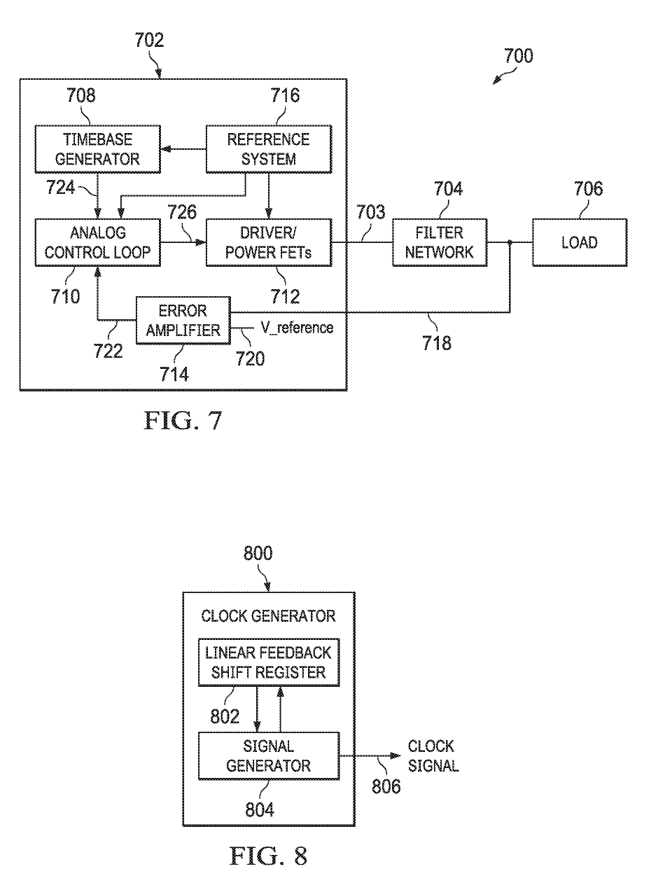

FIG. 7 shows a block diagram of an illustrative system 700. The system 700 provides an example of how a switch DC-to-DC converter chip or integrated circuit is used in an actual electronic system. In examples, the system 700 comprises a switch mode DC-to-DC converter chip 702 outputting a DC voltage 703 to a filter network 704 that supplies filtered DC power to a load 706. In examples, the system 700 is a mobile phone or another electronic device. The system 700 comprises other components that are not illustrated in FIG. 7. The filter network 704 may comprise inductors and capacitors to establish a filter. In examples, the load 706 is an electronic device or an electromechanical device that relies upon stable DC voltage power. In examples, the load 706 is a display screen of an electronic device, a microprocessor of an electronic device, a digital signal processor of an electronic device, an analog-to-digital converter (ADC), a power amplifier, a radio frequency power amplifier (RFPA), a radio transceiver of an electronic device, a vibrator motor of an electronic device, or yet other items. In examples, the DC-to-DC converter chip 702 is embodied in an integrated circuit.

The switch mode DC-to-DC converter chip 702 comprises a timebase generator 708, an analog control loop 710, a DC output driver 712, an error amplifier 714, and a reference system 716. In embodiments, the switch mode DC-to-DC converter chip 702 has more or fewer components. The voltage output by the filter network 704 to the load 706 is fed back into the switch mode DC-to-DC converter chip 702 to the error amplifier 714 as feedback 718 to promote the switch mode DC-to-DC converter chip 702 meeting its DC output voltage specifications. The error amplifier 714 is configured to amplify the difference between the feedback 718 and a voltage reference 720. An error signal 722 is output by the error amplifier 714 to the analog control loop 710 which uses this error signal 722 to adapt its drive signal 726 to the DC output driver 712.

The timebase generator 708 outputs a switching signal 724 to the analog control loop 710, and this switching signal 724 and the output of the error amplifier 714 is used to generate the desired DC voltage of the DC-to-DC converter chip 702. In examples, the timebase generator 708 is implemented as described above.

FIG. 8 shows a clock generator chip 800 or clock generator integrated circuit. The clock generator chip 800 may be used to provide a clock signal 806 to electronic components in an electronic device, for example to microprocessors (MPUs), to digital signal processors (DSPs), to graphical processing units (GPUs), to field programmable gate arrays (FPGAs), to complex programmable logic devices (CPLDs), to programmable logic devices (PLDs), to application specific integrated circuits (ASICs), dynamic random access memories (DRAMs), phase locked loops (PLLs), and to other electronic devices. The approach to spreading the spectrum of switching noise by dithering or varying the frequency of the clock is applicable to the clock generator chip 800 as well. In examples, the clock generator chip 800 comprises a LFSR 802 that is coupled to a signal generator 804. The LFSR 802 and signal generator 804 may be implemented and operated similarly to the timebase generator 102 and 200 described above.

In the foregoing discussion and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct connection or through an indirect connection via other devices and connections. Similarly, a device that is coupled between a first component or location and a second component or location may be through a direct connection or through an indirect connection via other devices and connections. An element or feature that is “configured to” perform a task or function may be configured (e.g., programmed or structurally designed) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof. In examples, the configuring may be performed by built-in software, firmware, or hardware logic providing auto adjusting and/or optimization of the operation based on the actual mode of operation of either the switch mode DC-to-DC converter chip 100 or on the load. Additionally, uses of the phrases “ground” or similar in the foregoing discussion are intended to include a chassis ground, an Earth ground, a floating ground, a virtual ground, a digital ground, a common ground, and/or any other form of ground connection applicable to, or suitable for, the teachings of the present disclosure. Unless otherwise stated, “about,” “approximately,” or “substantially” preceding a value means +/−10 percent of the stated value.

The above discussion is meant to be illustrative of the principles and various embodiments of the present disclosure. Numerous variations and modifications will become apparent to those skilled in the art once the above disclosure is fully appreciated. It is intended that the following claims be interpreted to embrace all such variations and modifications.

1. An integrated circuit, comprising:
a timebase generator that comprises a linear feedback shift register (LFSR), the timebase generator further comprising a constant current source and a variable current source; and
a switch mode direct current-to-direct current (DC-to-DC) voltage converter coupled to the timebase generator.

2. The integrated circuit of claim 1, wherein the LFSR is configured to control the timebase generator.

3. The integrated circuit of claim 1, wherein the LFSR is configured to vary a frequency of a timebase generated by the timebase generator, wherein the timebase is applied to control a switching signal of the switch mode DC-to-DC voltage converter.

4. The integrated circuit of claim 1, wherein the timebase generator comprises a signal generator that is configured to generate a timebase of the timebase generator, the LFSR is coupled to the signal generator, and the LFSR is configured to vary a frequency of the timebase of the timebase generator.

5. The integrated circuit of claim 4, wherein the LFSR is configured to vary the frequency of the timebase of the timebase generator based on a clock output of the signal generator coupled to the LFSR.

6. The integrated circuit of claim 5, wherein the timebase generator comprises a digital divider, the clock output is coupled to an input of the digital divider, the output of the digital divider is coupled to a clock input of the LFSR, and the digital divider is configured to reduce the frequency of the clock output of the signal generator by an integer power of 2.

7. The integrated circuit of claim 1, wherein the LFSR comprises a Galois LFSR.

8. The integrated circuit of claim 1, wherein the LFSR comprises a Fibonacci LFSR.

9. The integrated circuit of claim 1, wherein the LFSR comprises a Fibonacci LFSR configured to produce a maximum length sequence of output values.

10. An integrated circuit, comprising:
a timebase generator that comprises:
a Fibonacci linear feedback shift register (LFSR);
a comparator, a first input of the comparator coupled to the Fibonacci LFSR, a second input of the comparator coupled to a voltage reference, and an output of the comparator coupled to a clock input of the Fibonacci LFSR;
a constant current source; and
a variable current source coupled to the constant current source; and
a switch mode direct current-to-direct current (DC-to-DC) voltage converter coupled to the output of the comparator of the timebase generator.

11. The integrated circuit of claim 10, wherein the Fibonacci LFSR is configured to vary a frequency of a timebase signal produced by the comparator on its output.

12. The integrated circuit of claim 11, wherein the Fibonacci LFSR is configured to produce a maximum length sequence of pseudo-random numbers.

13. The integrated circuit of claim 12, wherein the Fibonacci LFSR is a 7-bit Fibonacci LFSR.

14. The integrated circuit of claim 10, wherein the timebase generator further comprises a digital divider, an input of the digital divider coupled to the output of the comparator and an output of the digital divider coupled to the clock input of the Fibonacci LFSR.

15. An integrated circuit, comprising:
a timebase generator that comprises:
a Fibonacci linear feedback shift register (LFSR), an output of an exclusive OR (XOR) gate of the Fibonacci LFSR coupled to an input of a register of the Fibonacci LFSR and two inputs of the XOR gate coupled to two outputs of registers of the Fibonacci LFSR;
a comparator, a first input of the comparator coupled to the Fibonacci LFSR, a second input of the comparator coupled to a voltage reference;
a digital divider, an input of the digital divider coupled to an output of the comparator and an output of the digital divider coupled to a clock input of the Fibonacci LFSR; and
a constant current source and a variable current source coupled to the comparator; and
a switch mode direct current-to-direct current (DC-to-DC) voltage converter coupled to the output of the comparator of the timebase generator.

16. The integrated circuit of claim 15, wherein the LFSR is a Fibonacci LFSR configured to produce a maximum length sequence of output values.

17. The integrated circuit of claim 16, wherein the Fibonacci LFSR is a 7-bit Fibonacci LFSR and comprises a first register, a second register, a third register, a fourth register, a fifth register, a sixth register, and a seventh register, wherein an output of the XOR gate is connected to an input of the seventh register, wherein an output of the seventh register is connected to a first input of the XOR gate and to an input of the sixth register, wherein an output of the sixth register is connected to an input of the fifth register, wherein an output of the fifth register is connected to an input of the fourth register, wherein an output of the fourth register is connected to an input of the third register, wherein an output of the third register is connected to an input of the second register, wherein an output of the second register is connected to the input of the first register, and wherein an output of the first register is connected to a second input of the XOR gate.

18. The integrated circuit of claim 15, wherein the Fibonacci LFSR is coupled to the comparator via the constant current source and the variable current source, wherein a summation of a current output by the constant current source and a current output by the variable current source varies the frequency of the timebase signal produced by the signal generator, and wherein the LFSR is configured to vary the frequency of a timebase signal produced by the comparator on its output by controlling the current output by the variable current source.

19. The integrated circuit of claim 18, wherein the signal generator further comprises a capacitor and an electronic switch, wherein the first input of the comparator is coupled to a first lead of the capacitor, a second lead of the capacitor is coupled to a ground, the output of the comparator is coupled to a control lead of the switch, a first lead of the switch is coupled to the first lead of the capacitor, a second lead of the switch is coupled to the ground, an output of the constant current source is coupled to the first lead of the capacitor, and an output of the varying current source is coupled to the first lead of the capacitor.

20. The integrated circuit of claim 15, wherein the Fibonacci LFSR is one of a 7-bit Fibonacci LFSR, a 9-bit Fibonacci LFSR, an 11-bit Fibonacci LFSR, a 15-bit Fibonacci LFSR, or a 17-bit Fibonacci LFSR.
